(19) United States
(12) Patent Application Publication
(10) Pub. No.: US 2024/0414967 A1
(43) Pub. Date: Dec. 12, 2024

(54) DISPLAY DEVICE AND A METHOD FOR MANUFACTURING A DISPLAY DEVICE

(71) Applicant: Samsung Display Co., LTD., Yongin-si (KR)

(72) Inventors: Hyun Eok SHIN, Yongin-si (KR); Su Kyoung YANG, Yongin-si (KR); Dong Min LEE, Yongin-si (KR)

(21) Appl. No.: 18/592,088

(22) Filed: Feb. 29, 2024

(30) Foreign Application Priority Data
Jun. 9, 2023 (KR) 10-2023-0074037

(51) Int. Cl. H10K 59/131; G09G 3/3225; H10K 59/12

(52) U.S. Cl. CPC H10K 59/1315; G09G 3/3225; H10K 59/1201; G09G 2300/0842

(57) ABSTRACT

The present disclosure may provide display device and a method for manufacturing a display device. According to an embodiment, a display device includes a substrate including a display area and a pad area. The display device includes a data conductive layer disposed on the substrate in the pad area. The data conductive layer includes a data base layer, a data main metal layer disposed on the data base layer, a first data capping layer disposed on the data main metal layer, a second data capping layer disposed on the first data capping layer, and a plurality of metal aggregates disposed on the second data capping layer.

### CROSS-REFERENCE TO RELATED APPLICATION

This application claims priority to Korean Patent Application No. 10-2023-0074037, filed on Jun. 9, 2023, and all the benefits accruing therefrom under 35 U.S.C. § 119, the content of which in its entirety is herein incorporated by reference.

### BACKGROUND

### 1. Field

The present disclosure relates to a display device and a method for manufacturing a display device.

### 2. Description of the Related Art

Display devices are becoming increasingly important with the development of multimedia. In response, various types of display devices such as, for example, organic light emitting displays (OLED) and liquid crystal displays (LCD), are being used.

A device for displaying an image of a display device may include a display panel such as, for example, an organic light emitting display panel or a liquid crystal display panel. Among the display panels, the light emitting display panel may include a light emitting element. For example, light emitting diodes (LED) may include organic light emitting diodes (OLED) that utilize organic materials as fluorescent materials, inorganic light emitting diodes that utilize inorganic materials as fluorescent materials, and the like.

### SUMMARY

Aspects and features of embodiments of the present disclosure provide a display device including a wiring structure that improves bonding characteristics of a pad region of the display device.

However, aspects of the present disclosure are not restricted to the examples set forth herein. The above and other aspects of the present disclosure will become more apparent to one of ordinary skill in the art to which the present disclosure pertains by referencing the detailed description of the present disclosure given herein.

According to an embodiment, A display device includes a substrate including a display area and a pad area and a data conductive layer disposed on the substrate in the pad area, wherein the data conductive layer includes a data base layer, a data main metal layer disposed on the data base layer, a first data capping layer disposed on the data main metal layer, a second data capping layer disposed on the first data capping layer, and a plurality of metal aggregates disposed on the second data capping layer.

The plurality of metal aggregates are formed of an inactive metal.

The inactive metal includes at least one metal selected from silver (Ag), gold (Au), and platinum (Pt).

The second data capping layer is formed of a transparent conductive oxide.

The second data capping layer includes indium tin zinc oxide (IGZO).

The second data capping layer has a thickness of about 100 Å to about 500 Å.

The first data capping layer includes titanium nitride (TiN).

The first data capping layer includes a thickness of about 100 Å to about 500 Å.

The data main metal layer includes aluminum (Al).

The data base layer includes titanium (Ti).

The data main metal layer is thicker than the data base layer, the first data capping layer, and the second data capping layer.

The data main metal layer has a thickness of 5,000 Å to 20,000 Å.

The data base layer has a thickness of 300 Å to 700 Å.

The substrate is any one of a rigid substrate, a flexible substrate, and an ultra thin glass (UTG) substrate.

According to an embodiment, a method for manufacturing a display device includes sequentially forming a patterned data base layer, a data main metal layer, a first data capping layer, and a second data capping layer on a substrate, forming a metal material layer on the second data capping layer and forming a metal aggregate by applying heat to the metal material layer such that metal included in the metal material layer is agglomerated.

The metal material layer includes an inactive metal.

The inactive metal includes at least one selected from silver (Ag), gold (Au), and platinum (Pt).

Wherein in the forming of the metal aggregate by applying the heat to the metal material layer such that metal included in the metal material layer is agglomerated, the heat is in a range of 100° C. to 250° C.

The metal aggregate includes at least one meal selected from silver (Ag), gold (Au), and platinum (Pt).

Wherein the second data capping layer includes indium tin zinc oxide (IGZO), the first data capping layer includes titanium nitride (TiN), the data main metal layer includes aluminum (Al), the patterned data base layer includes titanium (Ti).

According to example embodiments described herein, a display device having improved bonding characteristics of the pad region may be achieved using techniques implemented with a relatively low pressure and without conductive balls. In accordance with aspects of the present disclosure described herein, the techniques include heat-treating a metal (e.g., metal material included in a metal material layer) a relatively low temperature to form metal aggregates on a data conductive layer DCL.

However, the effects of the present disclosure are not limited to the aforementioned effects, and various other effects are included in the present specification.

### BRIEF DESCRIPTION OF THE DRAWINGS

FIG. 1 is a schematic plan view of a display device according to an embodiment.

FIG. 2 is a schematic cross-sectional view of the display device according to FIG. 1.

FIG. 3 is a schematic plan view of a circuit layer of a first display substrate of a display device according to an embodiment.

FIG. 4 is an equivalent circuit diagram of a pixel of a display device according to an embodiment.

FIG. 5 is an equivalent circuit diagram of a pixel of a display device according to another embodiment.

FIG. 6 is an equivalent circuit diagram of a pixel of a display device according to another embodiment.

FIG. 7 is a cross-sectional view of a first display substrate of a display device according to an embodiment.

FIG. 8 is an enlarged view of region A of FIG. 7.

FIG. 9 is a plan view illustrating a metal aggregate disposed on the second data capping layer of FIG. 8.

FIGS. 10 to 12 are cross-sectional views of processes for manufacturing a data conductive layer of the third region of the display device of FIG. 5.

FIG. 13 is a schematic diagram to illustrate bonding characteristics of a data conductive layer.

FIG. 14 is an electron micrograph of a surface of a data conductive layer having metal aggregates.

FIG. 15 is an electron micrograph of a cross-section of a data conductive layer having metal aggregates.

### DETAILED DESCRIPTION

In the following description, for the purposes of explanation, numerous specific details are set forth in order to provide a thorough understanding of various embodiments or implementations of the invention. As used herein, “embodiments” and “aspects” are interchangeable words that are non-limiting examples of devices or methods disclosed herein. It is apparent, however, that various embodiments may be practiced without these specific details or with one or more equivalent arrangements. Here, it is to be understood that various embodiments described herein do not have to be exclusive and do not limit the disclosure. For example, specific shapes, configurations, and characteristics of an embodiment may be used or implemented in another embodiment.

When an element, such as a layer, is referred to as being “on,” “connected to,” or “coupled to” another element or layer, the element may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. When an element is referred to as being “in contact,” “contacting,” or the like with another element, the element may be in “electrical contact” or in “physical contact” with the other element or may be in “indirect contact” or in “direct contact” with the other element.

Throughout the application, like reference numerals or symbols denote like elements. Further, in the accompanying drawings, the size and relative sizes of elements may be exaggerated for clarity and/or descriptive purposes.

Although the terms “first,” “second,” etc. may be used herein to describe various types of elements, these elements are not to be limited by these terms. These terms are used to distinguish one element from another element. Thus, a first element discussed below could be termed a second element without departing from the teachings of the disclosure.

The terms “about” or “approximately” as used herein is inclusive of the stated value and means within an acceptable range of deviation for the particular value as determined by one of ordinary skill in the art, considering the measurement in question and the error associated with measurement of the particular quantity (for example, the limitations of the measurement system). For example, “about” may mean within one or more standard deviations, or within +30%, 20%, 10%, or 5% of the stated value.

Unless otherwise specified, the illustrated embodiments are to be understood as providing example features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

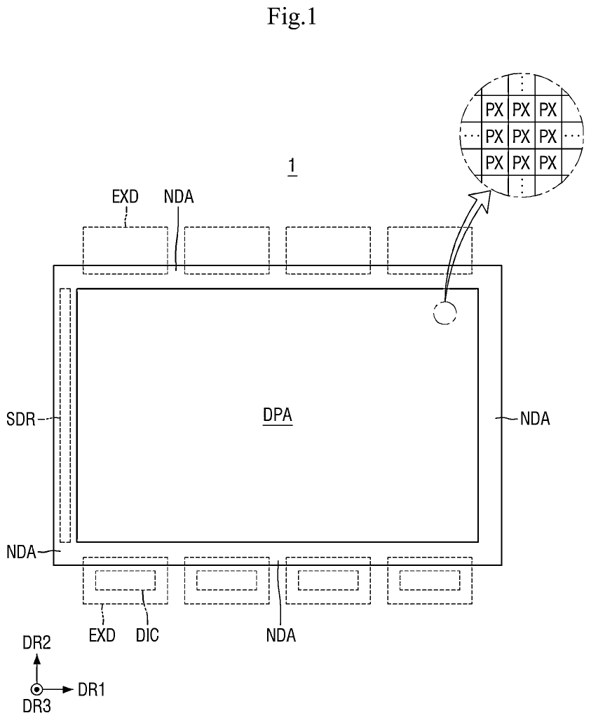

FIG. 1 is a schematic plan view of a display device 1 according to an embodiment.

Referring to FIG. 1, a display device 1 according to an embodiment may be applied to various consumer electronics, or internet-of-things (IoT) devices, such as, for example, smartphones, cell phones, tablet PC, personal digital assistants (PDA), portable multimedia players (PMP), televisions, gaming devices, watch-type electronic devices, head-mounted displays, monitors of personal computers, laptop computers, car navigation, car instrument panels, digital cameras, camcorders, exterior billboards, billboards, medical devices, inspection devices, refrigerators, washing machines, and the like. A television is described herein as an example of the display device 1, and the television may have a high or ultra-high resolution, such as, for example, HD, UHD, 4K, 8K, etc.

In addition, the display device 1 according to some embodiments may be variously categorized based on how the display device 1 is displayed. For example, the classification of the display device 1 may include an organic light emitting display device (OLED), an inorganic light emitting display device (inorganic EL), a quantum dot light emitting display device (QED), a micro-LED display device (micro-LED), a nano-LED display device (nano-LED), a plasma display device (PDP), a field emission display device (FED), a cathode ray display device (CRT), a liquid crystal display device (LCD), an electrophoretic display device (EPD), and the like. In the examples described herein, an organic light emitting display device is described as an example of the display device 1, and the organic light emitting display device applied in the example embodiments herein will be abbreviated or referred to simply as a display device unless otherwise indicated. However, embodiments of the display device 1 are not limited to an organic light emitting display device, and other display devices listed herein or known in the art may be employed as the display device 1 to the extent that they share technical ideas.

The display device 1 according to an embodiment may have a square shape, for example, a rectangular shape in a plan view. In an example, the display device 1 is a television, and the display device 1 is arranged such that the long sides of the rectangular shape are in the horizontal direction. However, aspects of the present disclosure are not limited thereto. For example, the long sides may be disposed in the longitudinal direction, and the display device 1 may be rotatably mounted such that the long sides are variably disposed in the horizontal or vertical direction.

The display device 1 may include a display area DPA and a non-display area NDA. The display area DPA may be an active area where the video is displayed. The display area DPA may have a square shape in a plan view similar to the rectangular shape of the display device 10 but is not limited thereto. For example, in a plan view, the shape (e.g., square shape, rectangular shape, or the like) of the display area DPA may correspond to the shape (e.g., square shape, rectangular shape, or the like) of the display device 1.

The display area DPA may include a plurality of pixels PX. The plurality of pixels PX may be arranged in a matrix orientation. The shape of each pixel PX may be rectangular or square in a plan view, but is not limited thereto. For example, the shape of each pixel PX may be rhombic in shape with each side inclined toward one side of the display device 10. The plurality of pixels PX may include multiple color pixels PX. For example, the plurality of pixels may include a first color pixel PX capable of emitting light of a red color, a second color pixel PX capable of emitting light of a green color, and a third color pixel PX capable of emitting light of a blue color, but are not limited thereto. in some embodiments, each color pixel PX may be alternately arranged in a stripe-type or a pentile-type.

The non-display area NDA may be disposed on the periphery of the display area DPA. The non-display area NDA may fully or partially enclose the display area DPA. The display area DPA may be a rectangular shape, and the non-display areas NDA may be arranged to be adjacent to the four sides of the display area DPA. The non-display area NDA may include a bezel of the display device 1.

A driving circuit or a driving element for driving the display area DPA may be disposed in the non-display area NDA. In an embodiment, a first non-display area NDA disposed adjacent to a first long side (lower side in FIG. 1) of the display device 1 and a second non-display area NDA disposed adjacent to a second long side (upper side in FIG. 1) are provided with pad portions on the display substrate of the display device 1, and an external device EXD may be mounted on the pad electrodes of the pad portions. Examples of the external device EXD include a connection film, a printed circuit board, a driving chip DIC, a connector, a wiring connection film, and the like. In the third non-display area NDA disposed adjacent to the first end side (left side in FIG. 1) of the display device 1, a scan driving unit SDR or the like may be disposed. In some examples, the scan driving unit SDR may be formed directly on the display substrate of the display device 1.

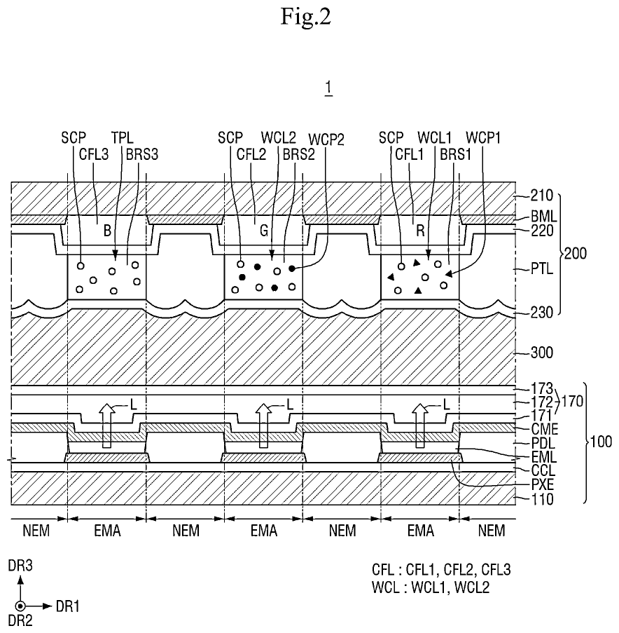

FIG. 2 is a schematic cross-sectional view of a display device 1 according to FIG. 1.

Referring to the example illustrated at FIG. 2, the display device 1 is a top emission type display device in which light L is emitted in a direction opposite (toward a second substrate 210) the direction of a first substrate 110 on which a light emitting layer EML is formed. However, embodiments of the present disclosure are not limited thereto, and the display device 1 may be a bottom emission type display device capable of emitting light L in the direction of the first substrate 110 on which the light emitting layer EML is formed. In some other embodiments, the display device 1 may be a double-sided emission type display device capable of emitting light in both the direction of the first substrate 110 and the direction of the second substrate 210.

Referring to FIG. 2, the display device 1 may include a first display substrate 100, a second display substrate 200 opposite the first display substrate 100, and a filling layer 300 bonding the first display substrate 100 and the second display substrate 200.

The first display substrate 100 may include the first substrate 110. The first substrate 110 may be an insulating substrate. The first substrate 110 may include a transparent material. For example, the first substrate 110 may include a transparent insulating material such as, for example, glass, quartz, or the like. The first substrate 110 may be a rigid substrate. However, the first substrate 110 is not limited thereto. For example, the first substrate 110 may include a plastic, such as, for example, polyimide, or the like, and the first substrate 110 may have flexible characteristics that enable the first substrate 110 to be warped, bent, folded, or rolled. In some embodiments, the first substrate 110 may be an ultra-thin glass (UTG) substrate.

A plurality of pixel electrodes PXE may be disposed on the first substrate 110. Each of the plurality of pixel electrodes PXE may be disposed for a given pixel PX. The pixel electrodes PXE of neighboring pixels PX may be separate from each other. For example, each pixel electrode PXE may be spaced apart from neighboring pixel electrodes PXE. A circuit layer CCL driving the pixels PX may be disposed on the first substrate 110. The circuit layer CCL may be disposed between the first substrate 110 and the pixel electrodes PXE. A detailed description of the circuit layer CCL will be described later herein.

Each pixel electrode PXE may be a first electrode of a light emitting diode, such as, for example, an anode electrode. The pixel electrode PXE may have a multilayer stack structure having one or more material layers with a high work function (e.g., greater than or equal to a target threshold work function) of indium-tin-oxide (ITO), indium-zinc-oxide (IZO), zinc oxide (ZnO), indium oxide (In₂O₃) and one or more reflective material layers such as, for example, silver (Ag), magnesium (Mg), aluminum (Al), platinum (Pt), lead (Pd), gold (Au), nickel (Ni), neodymium (Nd), iridium (Ir), chromium (Cr), lithium (Li), calcium (Ca), or a mixture thereof. In some embodiments, material layers having a higher work function may be disposed above the reflective material layer and respectively closer (e.g., in the direction DR3) to the light emitting layer EML. In some examples, the pixel electrode PXE may have a multilayer structure of ITO/Mg, ITO/MgF, ITO/Ag, or ITO/Ag/ITO, but is not limited thereto.

A pixel defining layer PDL may be disposed on a side (e.g., an upper side) of the first substrate 110 along the boundary of the pixel PX. The pixel defining layer PDL may be disposed on the pixel electrode PXE and may include an opening exposing the pixel electrode PXE. A light emitting area EMA may be separated from a non-emitting area NEM by the pixel defining layer PDL and the opening included in the pixel defining layer PDL. The pixel defining layer PDL may include organic insulating materials such as, for example, polyacrylates resin, epoxy resin, phenolic resin, polyamides resin, polyimides rein, unsaturated polyester resin, poly phenylenethers resin, poly phenylenesulfides resin, or benzocyclobutene (BCB). In some alternative and/or additional embodiments, the pixel defining layer PDL may include inorganic materials.

The light emitting layer EML may be disposed on the pixel electrode PXE exposed by the pixel defining layer PDL. In an embodiment in which the display device 1 is an organic light emitting display device, the light emitting layer EML may include an organic layer including an organic material. In some cases, the organic layer may include an organic light emitting layer and may further include at least one of a hole injection layer, a hole transport layer, an electron transport layer, and an electron injection layer as an auxiliary layer to assist light emission. In another embodiment in which the display device 1 is a micro-LED display device, a nano-LED display device, or the like, the light emitting layer EML may include an inorganic material such as, for example, an inorganic semiconductor.

In some embodiments, the light emitting layer EML may have a tandem structure including a plurality of organic light emitting layers stacked in the thickness direction (e.g., direction DR3) and a charge generating layer disposed between stacked organic light emitting layers. Each of the overlapping organic light emitting layers may emit light of the same wavelength. In some other embodiments, the organic light emitting layers may emit light of different wavelengths. In some embodiments, among the pixels PX, at least some layers of a light emitting layer EML of a pixel PX may be separate or different from at least some layers of a light emitting layer EML of a neighboring pixel PX. For example, the tandem structure of the light emitting layer EML of the pixel PX may be different from (e.g., due to a difference in one or more layers) the tandem structure of the light emitting layer EML of the neighboring pixel PX.

In an embodiment, the wavelength of light emitted by a light emitting layer EML may be the same for each color pixel PX. For example, the light emitting layer EML of each color pixel PX may emit blue light or ultraviolet light, and the color control structure described later herein may include a wavelength conversion layer WCL. In the example, a color may be displayed for each pixel PX based on the wavelength conversion layer WCL.

In other embodiments, the wavelength of light emitted by the light emitting layer EML may be different for each color pixel PX. For example, the light emitting layer EML of the first color pixel PX may emit light of a first color, the light emitting layer EML of the second color pixel PX may emit light of a second color, and the light emitting layer EML of the third color pixel PX may emit light of a third color.

A common electrode CME may be disposed on the light emitting layer EML. in some embodiments, the common electrode CME contacts the light emitting layer EML and contacts the upper surface of the pixel defining layer PDL.

The common electrode CME may be connected without distinction for each pixel PX. For example, the common electrode CME may be common or shared across pixels PX. In an example, the common electrode CME may be a front electrode disposed across the front of each pixel PX, without distinction of pixels PX. The common electrode CME may be a second electrode of a light emitting diode, such as, for example, the cathode electrode.

The common electrode CME may include a material layer with a small work function (e.g., a work function below a threshold value) such as, for example, Li, Ca, LiF/Ca, LiF/Al, Al, Mg, Ag, Pt, Pd, Ni, Au Nd, Ir, Cr, BaF, Ba, or compounds or mixtures thereof (e.g., a mixture of Ag and Mg). In some embodiments, the common electrode CME may further include a transparent metal oxide layer disposed on the small work function material layer.

The pixel electrode PXE, the light emitting layer EML, and the common electrode CME may together form or constitute a light emitting device (e.g., an organic light emitting device). Light emitted from the light emitting layer EML may be emitted in an upward direction through the common electrode CME.

A thin film encapsulation structure 170 may be disposed on the common electrode CME. The thin film encapsulation structure 170 may include at least one thin film encapsulation layer. For example, the thin film encapsulation layer may include a first inorganic film 171, an organic film 172, and a second inorganic film 173. The first inorganic film 171 and the second inorganic film 173 may each include silicon nitride (SiNx), silicon oxide (SiOx), or silicon oxynitride (SiOxNy). In some embodiments, the first inorganic film 171 and/or the second inorganic film 173 may each include at least one of silicon nitride (SiNx), silicon oxide (SiOx), and silicon oxynitride (SiOxNy). The organic film 172 may include organic insulating materials such as, for example, polyacrylates resin, epoxy resin, phenolic resin, polyamides resin, polyimides rein, unsaturated polyester resin, poly phenylenethers resin, poly phenylenesulfides resin, or benzocyclobutene (BCB).

The second display substrate 200 may be disposed on top of the thin film encapsulation structure 170 and face the thin film encapsulation structure 170. The second substrate 210 of the second display substrate 200 may include a transparent material. in some embodiments, the second substrate 210 may include a transparent insulating material, such as, for example, glass, quartz, or the like. The second substrate 210 may be a rigid substrate. However, the second substrate 210 is not limited thereto, and the second substrate 210 may include a plastic, such as, for example, polyimide, or the like, and may have flexible properties that allow the second substrate 210 to be warped, bent, folded, or rolled.

In some embodiments, the second substrate 210 may be the same substrate as the first substrate 110. For example, the second substrate 210 may be of the same material, thickness, transmittance, or the like as the first substrate 110. In some other embodiments, the second substrate 210 may be of a different material, thickness, transmittance, or the like compared to the first substrate 110. For example, the second substrate 210 may have a higher transmittance than the first substrate 110. The second substrate 210 may be thicker than the first substrate 110, or the second substrate 210 may be thinner than the first substrate 110.

A light blocking member BML may be disposed on a surface of the second substrate 210 facing the first substrate 110 along the boundary of the pixel PX. The light blocking member BML may overlap the pixel defining layer PDL of the first display substrate 100 and may be positioned in the non-emitting area NEM. The light blocking member BML may include an opening exposing one surface of the second substrate 210 overlapping the light emitting area EMA. The light blocking member BML may be formed in a lattice shape in a plan view.

The light blocking member BML may include an organic material. The light blocking member BML may absorb external light, which may reduce color distortion due to external light reflection. In some embodiments, the light blocking member BML may prevent light emitted from the light emitting layer EML from penetrating into adjacent pixels PX.

In an embodiment, the light blocking member BML may absorb light of all visible light wavelengths. The light blocking member BML may include a light absorbing material. For example, the light blocking member BML may be formed of a material used as a black matrix of the display device 1.

In another embodiment, the light blocking member BML may absorb light of a specific wavelength among light of a visible wavelength and transmit light of another specific wavelength. For example, the light blocking member BML may be formed of the same material as a single-color filter layer CFL (e.g., CFL1, CFL2, or CFL3). Specifically, in an example embodiment, the light blocking member BML may be formed of the same material as a third color filter layer CFL3 later described herein. In some embodiments, the light blocking member BML may be integrally formed with the third color filter layer CFL3. In some example implementations, the third color filter layer CFL3 may be a blue color filter layer. In some embodiments, the light blocking member BML may be omitted. In an example in which the light blocking member BML is omitted, the first capping layer 220 (to be later described herein) may directly contact the second substrate 210.

The color filter layer CFL may be disposed on a surface of the second substrate 210 on which the light blocking member BML is disposed. For example, the color filter layer CFL and the light blocking member BML may be disposed on a lower surface (e.g., in the direction DR3) of the second substrate 210. The color filter layer CFL may be disposed on a surface of the second substrate 210 exposed through the opening of the light blocking member BML. In some embodiments, the color filter layer CFL may also be partially disposed on the adjacent light blocking member BML.

The color filter layer CFL may include the first color filter layer CFL1 disposed on the first color pixel PX, the second color filter layer CFL2 disposed on the second color pixel PX, and the third color filter layer CFL3 disposed on the third color pixel PX. Each color filter layer CFL (e.g., first color filter layer CFL1, second color filter layer CFL2, third color filter layer CFL3) may include a colorant such as, for example, a dye or pigment that transmits light of a wavelength corresponding to the dye or pigment and absorbs light of other wavelengths. For example, the first color filter layer CFL1 may be a red color filter layer, the second color filter layer CFL2 may be a green color filter layer, and the third color filter layer CFL3 may be a blue color filter layer. Although the example of FIG. 2 illustrates a case where adjacent color filter layers CFL are spaced apart from each other on the light blocking member BML, adjacent color filter layers CFL may overlap at least partially on the light blocking member BML.

A first capping layer 220 may be disposed on the color filter layer CFL. The first capping layer 220 may prevent impurities such as, for example, moisture or air from penetrating from the outside and thereby damaging or contaminating the color filter layer CFL. In some embodiments, the first capping layer 220 may prevent the colorant of the color filter layer CFL from being diffused to other components.

The first capping layer 220 may directly contact a surface (lower surface in FIG. 2) of the color filter layer CFL. The first capping layer 220 may be formed of an inorganic material. For example, the first capping layer 220 may include at least one of silicon nitride, aluminum nitride, zirconium nitride, titanium nitride, hafnium nitride, tantalum nitride, silicon oxide, aluminum oxide, titanium oxide, tin oxide, and silicon oxynitride.

A partition wall PTL may be disposed on the first capping layer 220. The partition wall PTL may be disposed in the non-emitting area NEM. The partition wall PTL may be disposed such that the partition wall PTL overlaps the light blocking member BML. The partition wall PTL may include an opening exposing the color filter layer CFL. In some examples, the opening of the partition wall PTL may expose a portion of the first capping layer 220 overlapping the color filter layer CFL. The partition wall PTL may include a photosensitive organic material but is not limited thereto. In some examples, the partition wall PTL may further include a light blocking material.

The wavelength conversion layer WCL and/or a light transmitting layer TPL may be disposed in a space exposed by the opening of the partition wall PTL. In some embodiments, the wavelength conversion layer WCL and the light transmitting layer TPL may be formed by an inkjet process using the partition wall PTL as a bank. However, the formation of the wavelength conversion layer WCL and the light transmitting layer TPL is not limited thereto.

In an example embodiment in which the light emitting layer EML of each pixel PX emits a third color, the wavelength conversion layer WCL may include the first wavelength conversion pattern WCL1 (e.g., for converting the third color into a first color as later described herein) disposed on the first color pixel PX and the second wavelength conversion pattern WCL2 (e.g., for converting the third color into a second color as later described herein) disposed on the second color pixel PX. In the example embodiment, the light transmitting layer TPL may be disposed on the third color pixel PX.

The first wavelength conversion pattern WCL1 may include a first base resin BRS1 and a first wavelength conversion material WCP1 disposed in the first base resin BRS1. The second wavelength conversion pattern WCL2 may include a second base resin BRS2 and a second wavelength conversion material WCP2 disposed in the second base resin BRS2. The light transmitting layer TPL may include a third base resin BRS3, and a scatterer SCP disposed therein.

The first to third base resins BRS1, BRS2, and BRS3 may each include a light transmitting organic material. For example, the first to third base resins BRS1, BRS2, and BRS3 may each include an epoxy-based resin, an acrylic-based resin, a cardo-based resin, or an imide-based resin. In some embodiments, the first to third base resins BRS1, BRS2, and BRS3 may each include at least one of an epoxy-based resin, an acrylic-based resin, a cardo-based resin, and an imide-based resin. The first to third base resins BRS1, BRS2, and BRS3 may all be formed of the same material but are not limited thereto. For example, the first to third base resins BRS1, BRS2, and BRS3 may be formed of different respective materials or different respective combinations of materials.

The scatterers SCP may be metal oxide particles or organic particles. In some example embodiments, Titanium oxide (TiO₂), zirconium oxide (ZrO₂), aluminum oxide (Al₂O₃), indium oxide (In₂O₃), zinc oxide (ZnO), or tin oxide (SnO₂) may be exemplified as the metal oxide, and acrylic-based resin or urethane-based resin may be exemplified as the organic particle material.

In an example, the first wavelength conversion material WCP1 may convert light of the third color into light of the first color, and the second wavelength conversion material WCP2 may convert light of the third color into the second color. The first wavelength conversion material WCP1 and the second wavelength conversion material WCP2 may be in the form of quantum dots, quantum rods, or phosphors. The quantum dots may include group IV nanocrystals, group II-VI compound nanocrystals, group III-V compound nanocrystals, group IV-VI nanocrystals, or combinations thereof, in some embodiments, the first wavelength conversion pattern WCL1 and the second wavelength conversion pattern WCL2 may further include the scatterer SCP to increase wavelength conversion efficiency. For example, the scatterer SCP may control an emission path of light respectively incident the first wavelength conversion pattern WCL1 and the second wavelength conversion pattern WCL2.

The light transmitting layer TPL disposed on the third color pixel PX transmits light of the third color. For example, the light transmitting layer TPL may transmit light (of the third color) incident the light transmitting layer TPL from the light emitting layer EML while maintaining the wavelength of the light. The scatterer SCP of the light transmitting layer TPL may control an emission path of light incident and emitted through the light transmitting layer TPL. In the example illustrated at FIG. 2, the light transmitting layer TPL is absent the wavelength conversion material.

A second capping layer 230 is disposed on the wavelength conversion layer WCL, the light transmitting layer TPL, and the partition wall PTL. The second capping layer 230 may be formed of an inorganic material. The second capping layer 230 may include a material selected from the materials listed herein with reference to the first capping layer 220. The second capping layer 230 and the first capping layer 220 may be formed of the same material but are not limited thereto. For example, the second capping layer 230 and the first capping layer 220 may be formed of different respective materials or different respective combinations of materials.

The filling layer 300 may be disposed between the first display substrate 100 and the second display substrate 200. The filling layer 300 may be disposed such that the filling layer 300 fills a space between the first display substrate 100 and the second display substrate 200, and the filling layer 300 may adhere and couple the first display substrate 100 and the second display substrate 200 to each other. The filling layer 300 may be disposed between the thin film encapsulation structure 170 of the first display substrate 100 and the second capping layer 230 of the second display substrate 200. In some embodiments, the filling layer 300 may be formed of a Si-based organic material, an epoxy-based organic material, or the like, but is not limited thereto.

Hereinafter, example aspects of the circuit layer CCL of the display device 1 described herein will be described in detail.

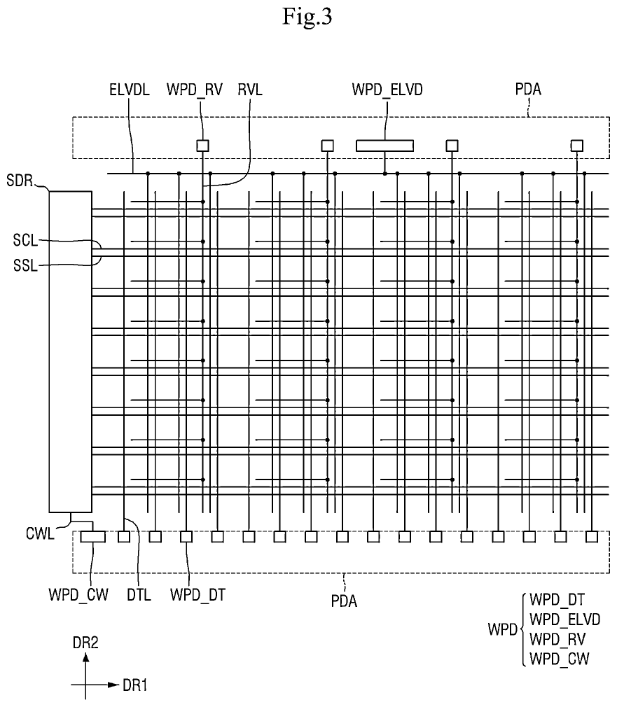

FIG. 3 is a schematic plan view of a circuit layer of a first display substrate of a display device 1 according to an embodiment.

Referring to FIG. 3, a plurality of lines is disposed on the first substrate 110. The plurality of lines may include a scan line SCL, a sensing signal line SSL, a data line DTL, a reference voltage line RVL, a first power supply line ELVDL, and the like. For example, though not illustrated, the plurality of lines may include lines other than the scan line SCL, the sensing signal line SSL, the data line DTL, the reference voltage line RVL, and the first power supply line ELVDL.

The scan line SCL and the sensing signal line SSL may extend in the first direction DR1. The scan line SCL and the sensing signal line SSL may be connected to the scan driving unit SDR. The scan driving SDR may include a driving circuit formed of the circuit layer CCL. The scan driving SDR may be disposed in the third non-display area NDA on the first substrate 110, but is not limited thereto. For example, the scan driving SDR may be disposed in a fourth non-display area NDA or in both the third and fourth non-display areas NDA. The fourth non-display area NDA may be disposed adjacent to an end side (right side in FIG. 1) of the display device 1. The scan driving unit SDR may be connected to a signal connection line CWL, and at least one end of the signal connection line CWL may be connected to an external device (“EXD” in FIG. 1) via a pad (WPD_CW) formed on the first non-display area NDA and/or the second non-display area NDA. For example, the techniques described herein may include forming a pad (WPD_CW) on the first non-display area NDA and/or the second non-display area NDA for connecting signal connection line CWL to the external device.

The data line DTL and the reference voltage line RVL may extend in the second direction DR2 intersecting the first direction DR1. The first power supply line ELVDL may include a portion extending in the second direction DR2. The first power supply line ELVDL may further include a portion extending in the first direction DR1. The first power supply line ELVDL may have a mesh structure but is not limited thereto.

Wiring pads WPD may be disposed at one or more ends of each of the data line DTL, the reference voltage line RVL, and the first power supply line ELVDL. Each wiring pad WPD may be disposed on a pad area PDA of the non-display area (NDA). In an embodiment, the wiring pad WPD_DT (hereinafter referred to as ‘data pad’) of the data line DTL may be disposed in the pad area PDA of the first non-display area NDA (e.g., the lower non-display area NDA), and the wiring pad WPD_RV (hereinafter referred to as ‘reference voltage pad’) of the reference voltage line RVL and the wiring pad WPD_ELVD (hereinafter referred to as ‘first power supply pad’) of the first power supply line ELVDL may be disposed in the pad area PDA of the second non-display area NDA (e.g., the upper non-display area NDA). As another example, the data pad WPD_DT, the reference voltage pad WPD_RV, and the first power supply pad WPD_ELVD may all be disposed in the same area, for example, the first non-display area NDA. An external device (“EXD” in FIG. 1) may be mounted on the wiring pad WPD as described herein. The external device EXD may be mounted on the wiring pad WPD through an anisotropic conductive film, ultrasonic bonding, or the like.

Each pixel PX on first substrate 110 includes a pixel driving circuit. The wiring described herein may pass through or around each pixel PX and apply a driving signal to each pixel driving circuit. The pixel driving circuit may include a transistor and a capacitor. The number of transistors and capacitors in each pixel driving circuit may be varied. Hereinafter, an example implementation is described in which the pixel driving circuit is of a 3T1C structure including three transistors and one capacitor. The pixel driving circuit is not limited thereto, and aspects of the present disclosure support various other modified pixel PX structures of the pixel driving circuit such as, for example, a 2T1C structure, a 7T1C structure, a 6T1C structure, and the like.

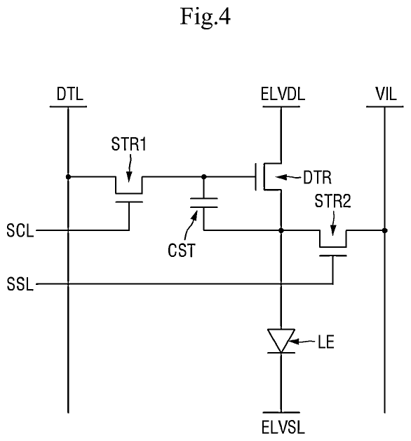

FIG. 4 is an equivalent circuit diagram of a pixel of a display device 1 according to an embodiment.

Referring to FIG. 4, each pixel PX of the display device according to an embodiment includes, in addition to the light emitting element LE, three transistors DTR, STR1 and STR2, and one capacitor CST. The capacitor CST may be a storage capacitor, example aspects of which are later described herein.

The light emitting element LE emits light in response to a current supplied through a driving transistor DTR. The light emitting element LE may be implemented as an inorganic light emitting diode, an organic light emitting diode, a micro light emitting diode, a nano light emitting diode, or the like.

A first electrode (i.e., an anode electrode) of the light emitting element LE may be connected to a source electrode of the driving transistor DTR, and a second electrode (i.e., a cathode electrode) of the light emitting element LE may be connected to a second power supply line ELVSL supplied with a low potential voltage (second power supply voltage) lower than a high potential voltage (first power supply voltage) of the first power supply line ELVDL.

The driving transistor DTR adjusts the current flowing to the light emitting element LE from the first power supply line ELVDL supplied with the first power voltage according to a voltage difference between a gate electrode and the source electrode of the driving transistor DTR. The gate electrode of the driving transistor DTR may be connected to a first electrode of a first transistor ST1, the source electrode of the driving transistor DTR may be connected to the first electrode of the light emitting element LE, and a drain electrode of the driving transistor DTR may be connected to the first power supply line ELVDL to which the first power supply voltage is applied.

The first transistor STR1 is turned-on by a scan signal on the scan line SCL. In an example, in the ON state, the first transistor STR1 connects the data line DTL to the gate electrode of the driving transistor DTR. The gate electrode of the first transistor STR1 may be connected to the scan line SL, the first electrode of the first transistor STR1 may be connected to the gate electrode of the driving transistor DTR, and a second electrode of the first transistor STR1 may be connected to the data line DTL.

A second transistor STR2 is turned-on by a sensing signal on the sensing signal line SSL, and in the ON state, the second transistor STR2 connects an initialization voltage line VIL to the source electrode of the driving transistor DTR. The gate electrode of the second transistor ST2 may be connected to the sensing signal line SSL, a first electrode of the second transistor STR2 may be connected to the initialization voltage line VIL, and the second electrode of the second transistor STR2 may be connected to the source electrode of the driving transistor DTR.

In an embodiment, the first electrode of each of the first and second transistors STR1 and STR2 may be the source electrode, and the second electrode of each of the first and second transistors STR1 and STR2 may be the drain electrode, but is not limited to. For example, the first electrode of each of the first and second transistors STR1 and STR2 may be the drain electrode, and the second electrode of each of the first and second transistors STR1 and STR2 may be the source electrode.

The capacitor CST is formed between the gate and source electrodes of the driving transistor DTR. In the example of FIG. 4, the capacitor CST is a storage capacitor capable of storing the difference voltage between the gate voltage of the driving transistor DTR and the source voltage of the driving transistor DTR.

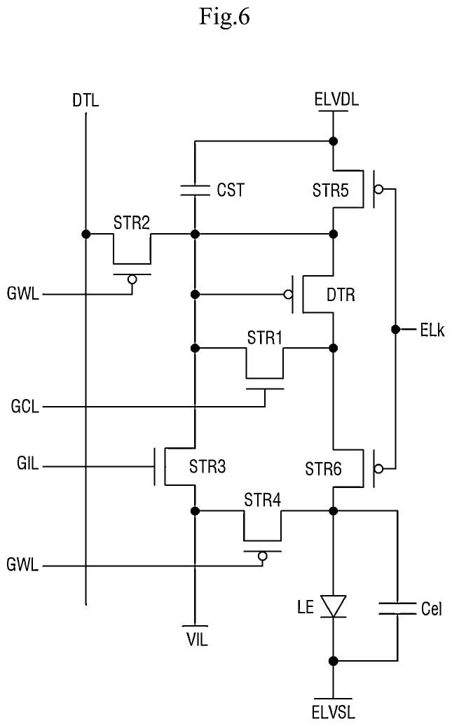

The driving transistor DTR and the first and second transistors STR1 and STR2 may be formed as thin film transistors. In some aspects, while FIG. 6 later illustrated herein describes the driving transistor DTR and the first and second switching transistors STR1 and STR2 as being N-type MOSFETs (metal oxide semiconductor field effect transistors), embodiments of the present disclosure are not limited thereto. For example, the driving transistor DTR and the first and second switching transistors STR1 and STR2 may each be a P-type MOSFET. In some other embodiments, one or more of the driving transistor DTR and the first and second switching transistors STR1 and STR2 may be an N-type MOSFET, and others may be a P-type MOSFET.

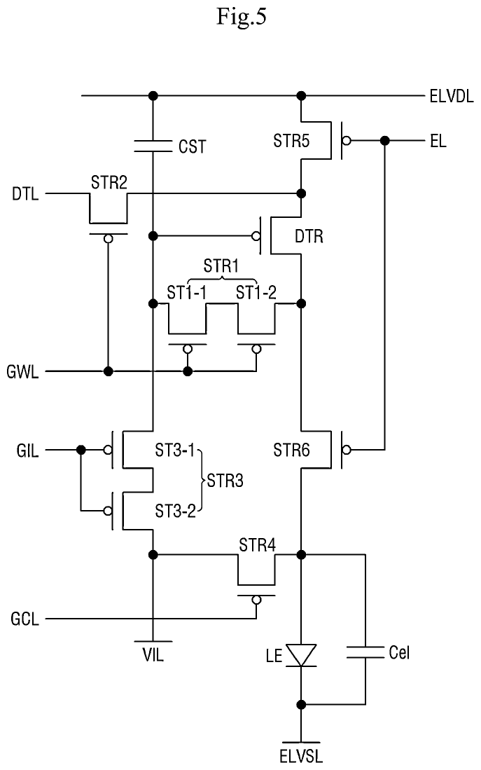

FIG. 5 is an equivalent circuit diagram of a pixel of a display device 1 according to another embodiment.

Referring to FIG. 5, the first electrode of the light emitting element LE may be connected to the first electrode of the fourth transistor STR4 and the second electrode of the sixth transistor STR6, and the second electrode of the light emitting element LE may be connected to the second power supply line ELVSL. A parasitic capacitance Ce1 may be formed between the first electrode and the second electrode of the light emitting element LE.

Each pixel PX includes the driving transistor DTR, switch elements, and the capacitor CST. The switch elements include first to sixth transistors STR1, STR2, STR3, STR4, STR5, and STR6.

The driving transistor DTR includes a gate electrode, a first electrode, and a second electrode as described herein. The driving transistor DTR controls the drain-to-source current Ids (hereinafter referred to as the “driving current”) flowing between the first and second electrodes of the driving transistor DTR based on the data voltage applied to the gate electrode of the driving transistor DTR.

The capacitor CST is formed between the second electrode of the driving transistor DTR and the first power supply line ELVDL. One electrode of the capacitor CST may be connected to the second electrode of the driving transistor DTR, and the other electrode may be connected to the first power supply line ELVDL.

When the first electrode of each of the first to sixth transistors STR1, STR2, STR3, STR4, STR5, and STR6 and the driving transistor DTR is the source electrode, the second electrode of each of the first to sixth transistors STR1, STR2, STR3, STR4, STR5, and STR6 and the driving transistor DTR may be the drain electrode. Alternatively, if the first electrode of each of the first to sixth transistors STR1, STR2, STR3, STR4, STR5, and STR6 and the driving transistor DTR is the drain electrode, the second electrode of each of the first to sixth transistors STR1, STR2, STR3, STR4, STR5, and STR6 and the driving transistor DTR may be the source electrode.

An active layer of each of the first to sixth transistors STR1, STR2, STR3, STR4, STR5, and STR6 and the driving transistor DTR may be formed from any of poly silicon, amorphous silicon, and oxide semiconductors. In an example in which the semiconductor layer of each of the first through sixth transistors STR1, STR2, STR3, STR4, STR5, and STR6 and the driving transistor DTR is formed from poly silicon, the process for forming the semiconductor layer may be a low temperature poly silicon (LTPS) process.

In some embodiments, though in the example described with reference to FIG. 5, the first to sixth transistors STR1, STR2, STR3, STR4, STR5, and STR6 and the driving transistor DTR are described as each being a P-type MOSFET (Metal Oxide Semiconductor Field Effect Transistor), aspects of the present disclosure are not limited thereto. For example, aspects of the present disclosure support implementations in which any or all of the first to sixth transistors STR1, STR2, STR3, STR4, STR5, and STR6 and the driving transistor DTR may be formed as an N-type MOSFET.

In some embodiments, aspects of the present disclosure support setting the first power supply voltage of the first power supply line ELVDL, the second power supply voltage of the second power supply line ELVSL, and the third power supply voltage of the third power supply line VIL in consideration of the characteristics of the driving transistor DTR, the characteristics of the light emitting element LE, and the like.

FIG. 6 is an equivalent circuit diagram of a pixel of a display device 1 according to another embodiment.

The display device 1 according to the example embodiment of FIG. 6 includes aspects of the display device 1 according to the example embodiments of FIGS. 4 and 5, and repeated descriptions of like elements are omitted for brevity. The embodiment of FIG. 6 differs from the embodiment of FIG. 4 in that the driving transistor DTR, the second transistor STR2, the fourth transistor STR4, the fifth transistor STR5, and the sixth transistor STR6 are formed as P-type MOSFETs, and the first transistor STR1 and the third transistor STR3 are formed as N-type MOSFETs.

Referring to FIG. 6, the active layer of each of the driving transistor DTR, second transistor STR2, fourth transistor STR4, fifth transistor STR5, and sixth transistor STR6 formed as P-type MOSFETs may be formed of polysilicon, and the active layer of each of the first transistor STR1 and third transistor STR3 formed as N-type MOSFETs may be formed of an oxide semiconductor.

FIG. 6 differs from the embodiment of FIG. 5 in that the gate electrode of the second transistor STR2 and the gate electrode of the fourth transistor STR4 are connected to the write scan line GWL, and the gate electrode of the first transistor STR1 is connected to the control scan line GCL. In the example in FIG. 6, the first transistor STR1 and the third transistor STR3 are formed as N-type MOSFETs, such that the scan signal with a gate ‘HIGH’ voltage may be applied to the control scan line GCL and the initialization scan line GIL. In some aspects, since the second transistor STR2, the fourth transistor STR4, the fifth transistor STR5, and the sixth transistor STR6 are formed as P-type MOSFETs, the scan signal with a gate ‘LOW’ voltage may be applied to the write scan wire GWL and the light emitting element LE.

It should be noted that the example equivalent circuit diagrams of a pixel PX according to embodiments of the present disclosure described herein are not limited to the examples described with reference to FIGS. 4 to 6. The equivalent circuit diagram of a pixel PX according to embodiments of the present disclosure may be formed by other known or suitable circuit structures that may be employed by those skilled in the art other than or in addition to the embodiments shown in FIGS. 4 to 6.

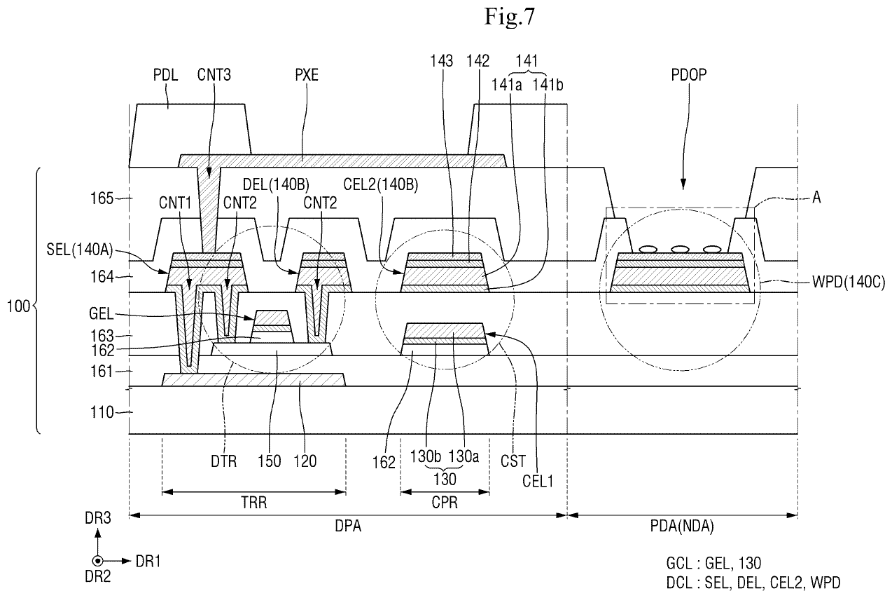

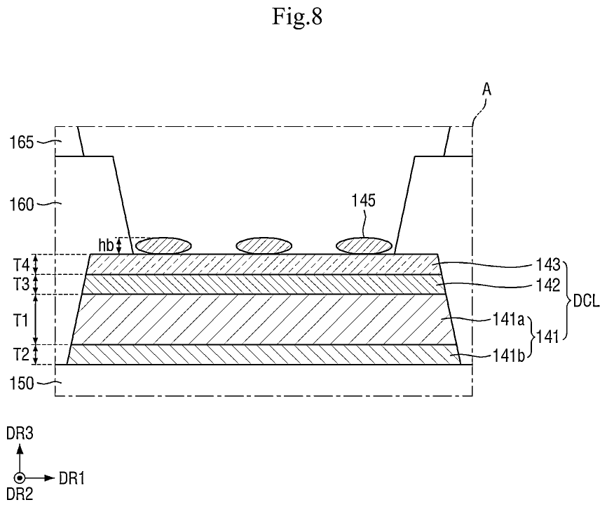

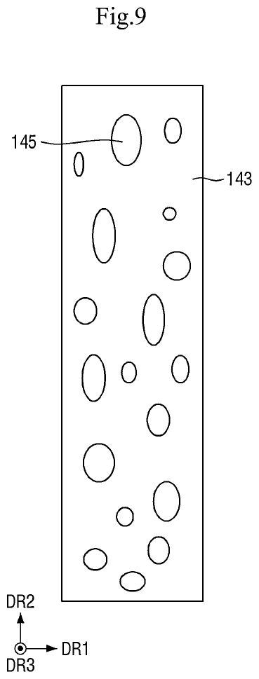

FIG. 7 is a cross-sectional view of a first display substrate of a display device 1 according to an embodiment. FIG. 8 is an enlarged view of region A of FIG. 7. FIG. 9 is a plan view illustrating a metal aggregate disposed on the second data capping layer of FIG. 8.

In FIG. 7, cross-sections of a portion of the display area DPA and a portion of the non-display area NDA are shown together. The cross-sections of a transistor area TRR and a capacitor area CPR of a pixel are shown in the cross-section of the display area DPA, and cross-sections of the pad area PDA are shown in the cross-section of the non-display area NDA. The transistor area TRR of FIG. 7 shows an area in which the driving transistor DTR is disposed among the three transistors. In FIG. 7, the circuit layer CCL of the first display substrate 100 of FIG. 2 is mainly shown, and the pixel defining layer PDL is shown in view of the stacked structure while omitting other features of the first display substrate 100. FIG. 8 illustrates the wiring pad WPD disposed in the pad area PDA according to an embodiment.

Referring to FIG. 7, the circuit layer CCL includes a semiconductor layer 150 disposed on the first substrate 110, a plurality of conductive layers, and a plurality of insulating layers. The semiconductor layer 150 may include an oxide semiconductor. The plurality of conductive layers may include a bottom metal layer 120, a gate line GCL, a data conductive layer DCL, and a pixel electrode PXE. The plurality of insulating layers may include a buffer layer 161, a gate insulating layer 162, an interlayer insulating layer 163, a passivation layer 164, and a via layer 165.

In some embodiments, the bottom metal layer 120 may be disposed on the first substrate 110. The bottom metal layer 120 may be a light blocking layer that serves to protect the semiconductor layer 150 from lower or internal light. The bottom metal layer 120 may have a patterned shape. The bottom metal layer 120 may be disposed in the transistor area TRR. The semiconductor layer 150 may be disposed on the bottom metal layer 120, and the bottom metal layer 120 may overlap the semiconductor layer 150 such that the bottom metal layer 120 covers the lower portion of the semiconductor layer 150. The bottom metal layer 120 may be disposed below the semiconductor layer 150 such that the bottom metal layer 120 covers at least a channel area of the semiconductor layer 150 and covers the entire semiconductor layer 150. The bottom metal layer 120 may be electrically connected to a source electrode SEL of the driving transistor DTR through a first contact hole CNT1, and the electrical connection may suppress a change in voltage of the driving transistor DTR. The bottom metal layer 120 may be formed of a low-reflection material capable of reducing reflection of light. The bottom metal layer 120 may be formed of, for example, a Ti/Cu double layer in which a titanium layer and a copper layer are stacked. However, embodiments of the present disclosure are not limited thereto, and the bottom metal layer 120 may be formed of a Ti/Cu/Ti triple layer or a Cu single layer.

The buffer layer 161 may be disposed on the bottom metal layer 120. The buffer layer 161 may be disposed to cover the entirety of the bottom metal layer 120. The buffer layer 161 may be disposed to cover the entire surface of the first substrate 110 on which the bottom metal layer 120 is formed. The buffer layer 161 may include silicon nitride, silicon oxide, or silicon oxynitride. In some embodiments, the buffer layer 161 may include one or more of silicon nitride, silicon oxide, and silicon oxynitride. In an embodiment, the buffer layer 161 may include a double layer of SiNx/SiOX.

The semiconductor layer 150 may be disposed on the buffer layer 161. The semiconductor layer 150 is disposed in the transistor area TRR and may include a channel of the transistor DTR. The semiconductor layer 150 may include an oxide semiconductor, and the oxide semiconductor may include, for example, any one or more of a binary compound (ABx), a ternary compound (ABxCy), a quaternary compound (ABxCyDz) containing indium, zinc, gallium, tin, titanium, aluminum, hafnium (Hf), zirconium (Zr), magnesium (Mg), and the like. In an embodiment, the semiconductor layer 150 may include indium tin zinc oxide (IGZO).

The gate insulating layer 162 may be disposed on the buffer layer 161. The gate insulating layer 162 may be formed in the same pattern as the gate line GCL, which will be described later herein. The gate insulating layer 162 disposed in the transistor area TRR may be disposed on the semiconductor layer 150, and the gate insulating layer 162 disposed in the capacitor area CPR may be disposed on the buffer layer 161. Sidewalls of the gate insulating layer 162 may be substantially aligned with sidewalls of a gate conductive layer GCL described later herein. For example, sidewalls of the gate insulating layer 162 may be substantially aligned with sidewalls of a gate electrode GEL and a gate metal layer 130, but are not limited thereto. The gate insulating layer 162 may include a silicon compound or a metal oxide. For example, the gate insulating layer 162 may include any one or more of silicon oxide, silicon nitride, silicon oxynitride, aluminum oxide, tantalum oxide, hafnium oxide, zirconium oxide, titanium oxide, and the like. In an embodiment, the gate insulating layer 162 may include a SiOx layer. However, embodiments of the present disclosure are not limited thereto, and the gate insulating layer 162 may include a double layer of SiOx/SiNx.

The gate conductive layer GCL may be disposed on the gate insulating layer 162. The gate conductive layer GCL may include the gate electrode GEL included in the transistor area TRR and a capacitor first electrode CEL1 (or a lower electrode) included in the capacitor area CPR. In some embodiments, the gate conductive layer GCL may include the scan line SCL and the sensing signal line SSL described herein. In some embodiments, the gate conductive layer GCL may be disposed such that the gate conductive layer GCL does not overlap the data conductive layer DCL of the pad area PDA, which will be described later herein.

The gate conductive layer GCL may be formed of a single layer or may be formed of multiple layers. In an embodiment, the gate conductive layer GCL may include a gate main metal layer 130a and a gate base layer 130b disposed under the gate main metal layer 130a. Both the gate main metal layer 130a and the gate base layer 130b may be formed of a conductive material. In some examples, the gate conductive layer GCL may be implemented without interposing an insulating layer between the constituent layers of the gate conductive layer GCL overlapping in the thickness direction. The gate main metal layer 130a and the gate base layer 130b may be collectively etched and patterned by a single mask process (e.g., during the same mask process).

The gate base layer 130b is disposed under the gate main metal layer 130a. The gate base layer 130b provides improvement to layer-forming properties such as, for example, adhesion of the gate main metal layer 130a. Additionally, or alternatively, the gate base layer 130b may serve to prevent a reactive material from entering the gate main metal layer 130a from the lower gate insulating layer 162. In some embodiments, the gate base layer 130b may prevent or reduce the diffusion of a material (e.g., copper) constituting the gate main metal layer 130a to an adjacent lower film. The gate base layer 130b may include a material such as, for example, titanium (Ti), tantalum (Ta), calcium (Ca), chromium (Cr), magnesium (Mg), nickel (Ni), or any suitable combination thereof, but is not limited thereto.

In some aspects, the gate main metal layer 130a plays a main role supportive of transmitting signals and may be formed of a low-resistance material. The gate main metal layer 130a may have a greater thickness than the gate base layer 130b and may be formed of a material with lower resistance compared to the gate base layer 130b. The gate main metal layer 130a may include a material such as, for example, copper (Cu), molybdenum (Mo), aluminum (Al), or silver (Ag), or any suitable combination thereof, but is not limited thereto.

Although not shown, the gate metal layer 130 may further include a gate capping layer disposed on the gate main metal layer 130a. The gate capping layer may cover the gate main metal layer 130a on top of the gate main metal layer 130a and protect the gate main metal layer 130a. The gate capping layer may directly contact the gate main metal layer 130a, but is not limited thereto, and the gate capping layer may have a smaller thickness than the gate main metal layer 130a and may be formed of a material with higher resistance compared to the gate main metal layer 130a. The gate capping layer may serve to protect the gate main metal layer 130a from a layer disposed on the gate conductive layer GCL or from an etchant or other chemicals used during a manufacturing process of the display device 1. In addition, the gate capping layer may prevent a material (e.g., copper) forming the gate main metal layer 130a from diffusing toward a layer which is upper adjacent the gate main metal layer 130a.

The interlayer insulating layer 163 may be disposed on the gate conductive layer GCL. The interlayer insulating layer 163 may be disposed entirely on the gate conductive layer GCL, the semiconductor layer 150 exposed by the gate conductive layer GCL, and the buffer layer 161 exposed by the gate conductive layer GCL and the semiconductor layer 150. The interlayer insulating layer 163 may include an inorganic insulating material such as, for example, silicon oxide, silicon nitride, silicon oxynitride, hafnium oxide, aluminum oxide, titanium oxide, tantalum oxide, zinc oxide, and the like. In an embodiment, the interlayer insulating layer 163 may include SiON.

In some aspects, in the example drawings, a case where the upper surface of the interlayer insulating layer 163 is flat in the display area DPA is illustrated for convenience of explanation, but aspects of the present disclosure are not limited thereto. For example, the interlayer insulating layer 163 formed of an inorganic material may have a surface shape reflecting a lower level difference. In this case, the relative comparison of the thickness of the interlayer insulating layer 163 for each section may be made by the thickness measured from the same flat reference surface (for example, the upper surface of the buffer layer 161), without the lower step structure.

The data conductive layer DCL may be disposed on the interlayer insulating layer 163. The data conductive layer DCL may include the source electrode SEL and drain electrode DEL included in the transistor area TRR, the capacitor second electrode CEL2 (or upper electrode) included in the capacitor area CPR, and the wiring pad WPD included in the pad area PDA.

The source electrode SEL and the drain electrode DEL may be connected to the semiconductor layer 150 through second contact holes CNT2 penetrating the interlayer insulating layer 163. The source electrode SEL may also be connected to the bottom metal layer 120 through the first contact hole CNT1 penetrating the interlayer insulating layer 163 and the buffer layer 161. In addition, the data conductive layer DCL may include the data line DTL, the reference voltage line RVL, and the first power supply line ELVDL described herein.

Referring to FIGS. 7 to 9, the data conductive layer DCL includes a data conductive metal layer 141 having a stacked structure, a first data capping layer 142 disposed on the data conductive metal layer 141, a second data capping layer 143 disposed on the first data capping layer 142, and a plurality of metal aggregates 145 disposed on the second data capping layer 143.

The data conductive metal layer 141 may be formed of a single layer or multiple layers. In an embodiment, the data conductive metal layer 141 may further include a data main metal layer 141a and a data base layer 141b disposed under the data main metal layer 141a in addition to the data main metal layer 141a.

The data base layer 141b, the data main metal layer 141a, the first data capping layer 142, and the second data capping layer 143 may all be formed of a conductive material. In some embodiments, the data conductive layer DCL may be implemented such that insulating layers are not interposed between each component layer of the data conductive layer DCL overlapping in the thickness direction. The data base layer 141b, the data main metal layer 141a, the first data capping layer 142, and the second data capping layer 143 may be collectively etched and patterned by a single mask process (e.g., during the same mask process). A description of a process of forming the stacked structure of the data conductive layer DCL will be described later herein. The term “data base layer” may be referred to as a base layer associated with forming a data line DTL, the term “data main metal layer” may refer to a metal layer associated with forming the data line DTL, the term “first data capping layer” may refer to a first capping layer formed on the data line DTL, and the term “second data capping layer” may refer to a second capping layer formed on the data line DTL.

The data base layer 141b, similar to the gate base layer 130b, may provide improvement to layer-forming properties of the data main metal layer 141a, such as, for example, adhesion. In some aspects, the data base layer 141b prevents a reactive material from entering the data main metal layer 141a from the lower interlayer insulating layer 163. The data base layer 141b may include one or more selected from titanium (Ti), tantalum (Ta), calcium (Ca), chromium (Cr), magnesium (Mg), or nickel (Ni), but is not limited thereto. In an embodiment, the data base layer 141b may be formed of titanium. The thickness of the first data base layer 141b may range from about 300 Å to about 700 Å.

The data main metal layer 141a plays a main role supportive of transmitting signals and may be formed of a low resistance material. The data main metal layer 141a may have a greater thickness than the data base layer 141b, the first data capping layer 142, and the second data capping layer 143. The data main metal layer 141a may be formed of a material of lower resistance than the first data capping layer 142 disposed directly above the data main metal layer 141a and the data base layer 141b disposed directly below the data main metal layer 141a. The data main metal layer 141a may include one or more of the following materials selected from copper (Cu), aluminum (Al), silver (Ag), or molybdenum (Mo), but is not limited thereto. In an embodiment, the data main metal layer 141a may be formed of aluminum (Al).

The first data capping layer 142 covers and protects the data main metal layer 141a from above the data main metal layer 141a. The first data capping layer 142 may serve to protect the data main metal layer 141a when the second data capping layer 143 is exposed to and etched by an etchant or other chemicals used during a manufacturing process (e.g., a process of forming the pixel electrode PXE) after the formation of the data conductive layer DCL, which will be described later herein. In some aspects, the first data capping layer 142 may prevent a material (e.g., aluminum) constituting the data main metal layer 141a from diffusing toward an adjacent upper layer. The first data capping layer 142 may directly contact the data main metal layer 141a.

The first data capping layer 142 may include a single film of titanium nitride (TiN). In some additional and/or alternative embodiments, the first data capping layer 142 may be a multi-layer film including titanium nitride (TiN) or the like.

The second data capping layer 143 may be disposed on the first data capping layer 142. The second data capping layer 143 may serve to protect the first data capping layer 142 from dry etching during a manufacturing process (e.g., a process of forming a third contact hole CNT3 and a process of forming a pad opening PDOP) after the formation of the data conductive layer DCL, which will be described later herein. In some aspects, the first data capping layer 142 may prevent the thickness of the first data capping layer 142 from increasing. For example, the second data capping layer 142 prevents the thickness of the first data capping layer 142 due to concerns that the first data capping layer 142 may be etched by the dray etching by preventing the thickness of the first data capping layer 142 from increasing.

The second data capping layer 143 may include a material that is not consumed by the dry etching. In some embodiments, the second data capping layer 143 may be formed any one or more of indium gallium zinc oxide (IGZO), indium tin oxide (ITO), and indium gallium zinc oxide (IGZO). In some embodiments, the second data capping layer 143 may be formed of a material selected from the group consisting of indium gallium zinc oxide (IGZO), indium tin oxide (ITO), and indium gallium zinc oxide (IGZO). For example, the second data capping layer 143 may be formed of a single layer selected from an IGZO layer, an ITO layer, and an IZO layer, but is not limited thereto. In another example, the second data capping layer 143 may be a multilayer formed of any combination of an IGZO layer, an ITO layer, and an IZO layer. In an embodiment, the second data capping layer 143 may be formed of an IGZO single film. In an embodiment, the second data capping layer 143 may be formed of an IGZO single layer.

The plurality of metal aggregates 145 may be disposed on the second data capping layer 143. Each aggregate 145 may be different in size and shape from each other. Additionally, or alternatively, two or more of the metal aggregates 145 may be equal in size and shape.

Each metal aggregate 145 may be formed of an inert metal. For example, the metal aggregate 145 may be formed of a material selected from the group consisting of gold (Au), silver (Ag), and platinum (Pt). In an embodiment, the metal aggregate 145 may be formed of a single metal (e.g., silver (Ag)). In one or more additional and/or alternative embodiments, the metal aggregate 145 may be formed of any suitable combination of gold (Au), silver (Ag), and platinum (Pt).

The metal aggregate 145 has excellent bonding properties with the second data capping layer 143 and excellent bonding properties with other inert metals.

In an embodiment, the second data capping layer 143 is formed of an IGZO single layer. In some embodiments, when the metal aggregate 145 formed of a single metal of silver (Ag) is disposed on the second data capping layer 143, the metal aggregate 145 may be easily bonded to the second data capping layer 143 because the bonding characteristics between silver (Ag) and IGZO are excellent.

In an embodiment, the main metal layer 141a may include aluminum (Al), the first data capping layer 142 may include titanium nitride (TiN), the second data capping layer 143 may include IGZO, and the metal aggregates 145 may include silver (Ag).

In the example embodiment, through the adoption of titanium nitride (TiN) at the first data capping layer 142, the first data capping layer 142 does not form an oxide film, and the display device 1 may be formed without high pressing. In some aspects, as the metal aggregate 145 is formed on the second data capping layer 143, disposing a separate conductive ball at the second data capping layer 143 may be omitted. Furthermore, since silver (Ag) is a metal in the same group as gold (Au), and silver (Ag) and gold (Au) have good bonding properties with each other, silver (Ag) may be easily bonded to materials including gold (Au).

In an embodiment, side surfaces (or sidewalls) of the data base layer 141b, the main data metal layer 141a, the first data capping layer 142, and the second data capping layer 143 may be aligned with each other. That is, an upper surface of a layer constituting the data conductive layer DCL and a lower surface of another layer constituting the data conductive layer DCL disposed on the upper surface and in contact with the upper surface may be aligned without protruding from each other.

Referring to FIG. 8, the data main metal layer 141a, the data base layer 141b, the first data capping layer 142, and the second data capping layer 143 of the data conductive layer DCL may have different thicknesses. The respective thicknesses T1, T2, T3, and T4 of the conductive layers 141b, 141a, 142, and 143 constituting the data conductive layer DCL may be defined as the distance from the lower surface to the upper surface of each of the respective conductive layers 141b, 141a, 142, and 143.

In an embodiment, the thickness T1 of the data main metal layer 141a may be greater than each of the thickness T2 of the data base layer 141b, the thickness T3 of the first data capping layer 142, and the thickness T4 of the second data capping layer 143. In an embodiment, the thickness T1 of the data main metal layer 141a may be greater than a combined thickness of the thickness T2 of the data base layer 141b, the thickness T3 of the first data capping layer 142, and the thickness T4 of the second data capping layer 143.

The data base layer 141b and the first data capping layer 142 may be formed with respective thicknesses T2 and T3. The data base layer 141b and the first data capping layer 142 may be formed such that the data base layer 141b and first data capping layer 142 directly contact the data main metal layer 141a at the bottom and top of the data main metal layer 141a, respectively. The thicknesses T2 and T3 and the direct contact with the data main metal layer 141a are supportive of protecting the data main metal layer 141a.

In an embodiment, the data conductive layer DCL is a quadruple layer of Ti/Al/TiN/IGZO, in which the data main metal layer 141a includes Ti, the data base layer 141b includes Al, the first data capping layer 142 includes TiN, and the second data capping layer 143 includes IGZO. In the example embodiment, the thickness T1 of the data main metal layer 141a may be from 5,000 Å to 20,000 Å, the thickness T2 of the data base layer 141b may be from 300 Å to 700 Å, the thickness T3 of the first data capping layer 142 may be from 100 Å to 500 Å, and the thickness T4 of the second data capping layer 143 may be from 100 Å to 500 Å.

Referring back to FIG. 7, the data conductive layer DCL may include a first area 140B, a second area 140A, and a third area 140C. The respective shapes and sizes of the first area 140B, the second area 140A, and the third area 140C may be based on the structure of the second data capping layer 143 disposed on the uppermost layer of the data conductive layer DCL and/or the layer in contact with an upper surface of the second data capping layer 143.

The second data capping layer 143 of the data conductive layer DCL may have a different structure in a first area 140A, the second area 140B, and the third area 140C. Additionally, or alternatively, the data conductive layer DCL may have a different layer contacting the upper surface of the second data capping layer 143, at each of the first area 140A, the second area 140B, and the third area 140C. A detailed description of the first area 140A, the second area 140B, and the third 140C of the data conductive layer DCL will be described later herein.

The passivation layer 164 may be disposed on the data conductive layer DCL. The passivation layer 164 serves to cover and protect the data conductive layer DCL. The passivation layer 164 may include an inorganic insulating material such as, for example, silicon oxide, silicon nitride, silicon oxynitride, hafnium oxide, aluminum oxide, titanium oxide, tantalum oxide, zinc oxide, and the like, or a combination of the inorganic insulating materials.

The passivation layer 164 may be formed entirely in the display area DPA. In some aspects, the passivation layer 164 may be formed such that the passivation layer 164 is absent in at least a portion of the non-display area NDA (e.g., as illustrated at FIG. 7). For example, the passivation layer 164 may be disposed such that the passivation layer 164 is absent on at least a portion of the third area on 140C or the wiring pad WPD of the data conductive layer DCL of the pad area PDA included in the non-display area NDA.

The via layer 165 may be disposed on the passivation layer 164. The via layer 165 may cover the upper surface of the passivation layer 164 and expose side surfaces of an end of the passivation layer 164 disposed in the pad area PDA. In some aspects, the via layer 165 may cover a portion of the upper surface of the passivation layer 164 in the pad area PDA.

The via layer 165 may include the pad opening PDOP exposing at least a portion of the passivation layer 164 and the third area 140C of the data conductive layer DCL of the pad area PDA. The via layer 165 constituting an inner wall of the pad opening PDOP may expose end surfaces of the passivation layer 164 disposed in the pad area PDA but is not limited thereto. For example, the pad opening PDOP is formed by the passivation layer 164 and the via layer 165 disposed in the pad area PDA, and the inner walls of the passivation layer 164 constituting the pad opening PDOP and the via layer 165 may be aligned with each other. In some aspects, in the pad area PDA, the end surfaces of the passivation layer 164 may protrude further inward compared to the end surfaces of the via layer 165. In some embodiments (not illustrated), the via layer 165 may form the inner wall of the pad opening PDOP by covering side surfaces of an end of the passivation layer 164 disposed in the pad area PDA.

The via layer 165 may be formed of a polyacrylates resin, epoxy resin, phenolic resin, polyamides resin, polyimides rein, or unsaturated polyester resin, poly phenylenethers resin, polyphenylenesulfides resin, or an organic insulating material such as, for example, benzocyclobutene (BCB), or a combination of the described materials. The via layer 165 may further include a photosensitive material but is not limited thereto. In an embodiment, the via layer 165 may be formed of polyimide.

The pixel electrode PXE may be disposed on the via layer 165. A material constituting the pixel electrode PXE is as described with reference to FIG. 2. In an embodiment, the pixel electrode PXE may include a triple layer of ITO/Ag/ITO.

The pixel electrode PXE is disposed in the display area DPA and may be disposed such that the pixel electrode PXE is not included in the non-display area NDA. The pixel electrode PXE may overlap the transistor area TRR and the capacitor area CPR of the display area DPA, but is not limited thereto. The pixel electrode PXE may be connected to the source electrode SEL of the driving transistor DTR through the third contact hole CNT3 penetrating the via layer 165 and the passivation layer 164.

The pixel defining layer PDL may be disposed on the pixel electrode PXE. A material constituting the pixel defining layer PDL is the same as described with reference to FIG. 2. In an embodiment, the pixel defining layer PDL may include polyimide.

The pixel defining layer PDL is disposed in the display area DPA and may be disposed such that the pixel defining layer PDL is not included in the non-display area NDA. The pixel defining layer PDL may be disposed such that the pixel defining layer PDL overlaps an edge portion of the pixel electrode PXE. The pixel defining layer PDL may also be disposed on the via layer 165 on which the pixel electrode PXE is not formed.

In the following description, the first area 140A, second area 140B, and third area 140C of the above-described data conductive layer DCL will be described in detail.

The data conductive layer DCL may include the first area 140A overlapping the third contact hole CNT3, the second area 140B entirely covered by the passivation layer 164, and the third area 140C exposed by the pad opening PDOP. The first area 140A and the second area 140B of the data conductive layer DCL may be disposed in the display area DPA, and the third area 140C of the data conductive layer DCL may be disposed in the non-display area NDA.

The first area 140A of the data conductive layer may be disposed in the transistor area TRR. The source electrode SEL of the driving transistor DTR may be formed in the first area 140A of the data conductive layer DCL disposed in the transistor area TRR. The second area 140B of the data conductive layer DCL may be disposed in the transistor area TRR and/or the capacitor area CPR of the display area DPA. The source/drain electrodes SEL and DEL of the driving transistor DTR or the second electrode CEL2 of the capacitor CST may be formed in the second area 140B of the data conductive layer DCL.

The first area 140A of the data conductive layer DCL may be connected to the pixel electrode PXE through the third contact hole CNT3. Specifically, for example, the passivation layer 164 and the pixel electrode PXE may be disposed on the upper surface of the second data capping layer 143 included in the first area 140A of the data conductive layer DCL. At least a portion of the upper surface of the second data capping layer 143 included in the first area 140A of the data conductive layer DCL overlapping the third contact hole CNT3 may contact the pixel electrode PXE, and the remaining portion of the upper surface of the second data capping layer 143 included in the first area 140A of the data conductive layer DCL may contact the passivation layer 164. The pixel electrode PXE may be electrically connected by filling the inner space of the third contact hole CNT3 with the pixel electrode PXE such that the pixel electrode PXE contacts the upper surface of the second data capping layer 143 included in the first area 140A of the data conductive layer DCL overlapping the third contact hole CNT3.

The passivation layer 164 may be disposed on an upper surface of the second area 140B of the data conductive layer DCL. Specifically, an upper surface of the second data capping layer 143 included in the second area 140B of the data conductive layer DCL may contact the passivation layer 164. The passivation layer 164 disposed on the upper surface of the second data capping layer 143 included in the second area 140B of the data conductive layer DCL may be disposed entirely on the upper surface of the second data capping layer 143 of the second area 140B of the data conductive layer DCL such that the passivation layer 164 completely covers the second area 140B of the data conductive layer DCL.

The third area 140C of the data conductive layer DCL may be disposed in the pad area PDA. The wiring pad WPD of the pad area PDA may be formed in the third area 140C of the data conductive layer DCL disposed in the pad area PDA.

A plurality of metal aggregates 145 may be disposed on an upper surface of the second data capping layer 143 included in the third area 140C of the data conductive layer DCL. The height of each of the metal aggregates 145 may be about 100 Å to about 300 Å. In some examples, the metal aggregates 145 may be equal in height or be of different heights. The height of each metal aggregate 145 may be defined as the distance from the lower surface to the upper surface of the metal aggregate 145.

At least a portion of the upper surface of the second data capping layer 143 on which the metal aggregate 145 is not disposed in the third area 140C of the data conductive layer DCL may be exposed. Accordingly, for example, the upper surface of the second data capping layer 143 of the third area 140C of the data conductive layer DCL and the plurality of metal aggregates 145 may be exposed through the pad opening PDOP.

Hereinafter, a method of manufacturing the data conductive layer DCL of the display device of FIG. 8 will be described.

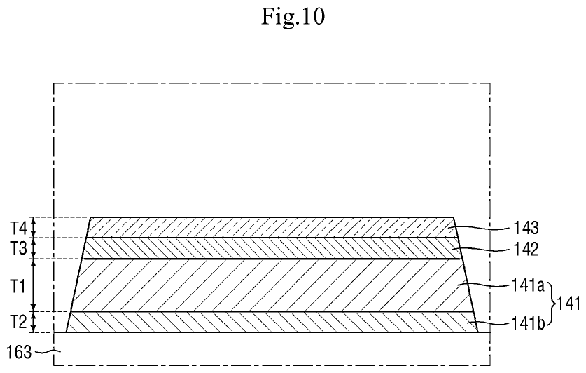

FIGS. 10 to 12 are cross-sectional views of processes for manufacturing a data conductive layer of the third region of the display device of FIG. 5.

Referring to FIG. 10, first, a patterned data conductive layer DCL is formed on the interlayer insulating layer 163 of the first substrate 110. The patterned data conductive layer DCL may be formed by a mask process. For example, material layers for the data conductive metal layer 141, a material layer for the first data capping layer 142, and a material layer for the second data capping layer 143 are sequentially deposited on the entire surface of the interlayer insulating layer 163. Here, the material layers for the data conductive metal layer 141 may include a material layer for the data base layer 141b and a material layer for the data main metal layer 141a.

In an embodiment, when the data conductive layer DCL has a quadruple structure of Ti/Al/TiN/IGZO, the material layer for the data base layer 141b including titanium (Ti), the material layer for the data main metal layer 141a including aluminum (Al), the material layer for the first data capping layer 142 including titanium nitride (TiN), and the material layer for the second data capping layer 143 including IGZO may be formed by sputtering among physical vapor deposition PVD.

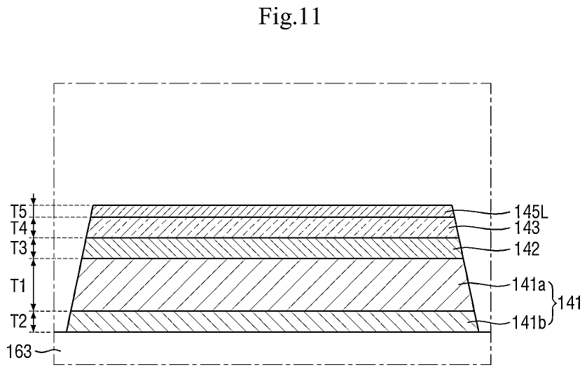

Next, referring to FIG. 11, a metal material layer 145L is deposited on the second data capping layer 143. The metal material layer 145L may include an inert metal. The metal material layer 145L may include, for example, a material selected from the group consisting of gold (Au), silver (Ag), and platinum (Pt). In some embodiments, the metal material layer 145L may include, for example, one or more of gold (Au), silver (Ag), and platinum (Pt).

The metal material layer 145L may be deposited according to a thickness T5 that is less than each of the thicknesses T2, T1, T3, and T4 of the data base layer 141b, the data main metal layer 141a, the first data capping layer 142, and the second data capping layer 143. The thickness T5 of the metal material layer 145L may be about 100 Å to about 200 Å.

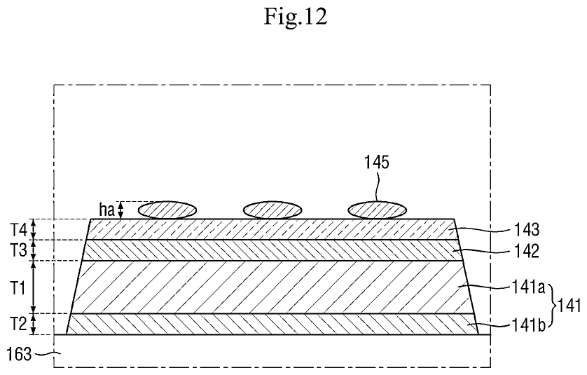

Referring to FIG. 12, the metal aggregate 145 is formed by applying heat to the metal material layer 145L. For example, forming the metal aggregate 145 may include applying heat of a preset temperature to the metal material layer 145L.

Specifically, for example, when heat of the preset temperature is applied to the metal material layer 145L, the metal material included in the metal material layer 145L is agglomerated to produce the metal aggregate 145. In some embodiments, the preset temperature may be a relatively low temperature of about 100° C. to 250° C. However, aspects of the present disclosure are not limited thereto, and the preset temperature may include any suitable temperature supportive of agglomerating the metal material in accordance with the techniques described herein.

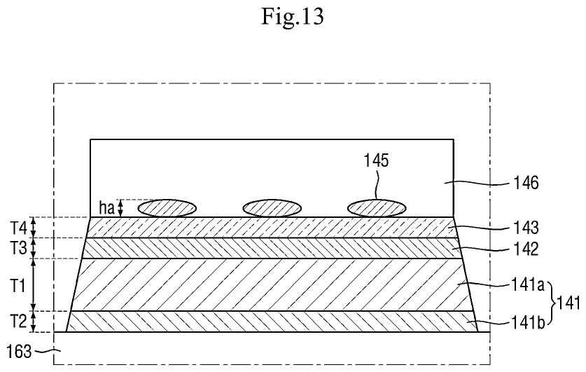

FIG. 13 is a schematic diagram to illustrate bonding characteristics of a data conductive layer DCL in accordance with example aspects of the present disclosure.

The metal aggregate 145 formed on the data conductive layer DCL described with reference to FIGS. 10 to 12 may be easily bonded to metal 146 of the same group metal. In an embodiment, when the data conductive layer DCL is a Ti/Al/TiN/IGZO quadruple film and the metal aggregate 145 including silver (Ag) is formed on the IGZO, the metal 146 may be gold (Au). Gold (Au) is a metal in the same group as silver (Ag) and has excellent bonding properties, such that gold (Au) and silver (AG) may be easily bonded to each other. In addition, since gold (Au) has excellent adhesion with IGZO, gold (Au) has excellent adhesion with the second data capping layer 143 on which the silver (Ag) aggregate 145 is not disposed.

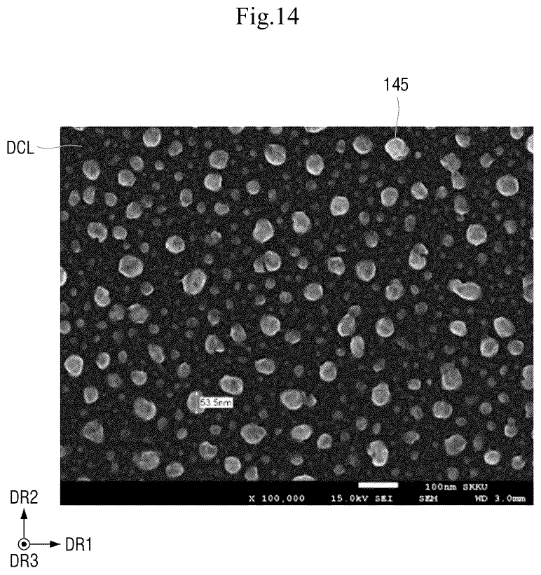

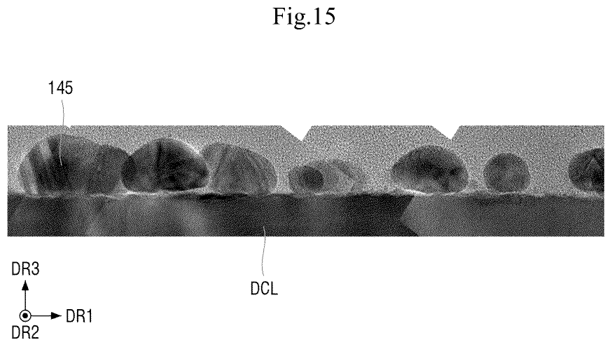

FIG. 14 is an electron micrograph of a surface of a data conductive layer DCL having metal aggregates. FIG. 15 is an electron micrograph of a cross-section of a data conductive layer DCL having metal aggregates.

Referring to FIGS. 14 and 15, the metal aggregate 145 is shown agglomerated on the data conductive layer DCL.

As described herein, improved bonding characteristics of a pad area may be achieved using techniques implemented at a relatively low pressure and without conductive balls. In accordance with aspects of the present disclosure described herein, the techniques include heat-treating metal (e.g., metal material included in metal material layer 145L) at a relatively low temperature to form metal aggregates 145 on the data conductive layer DCL.

However, the aspects of the disclosure are not restricted to the examples set forth herein. The above and other aspects of the disclosure will become more apparent to one of daily skill in the art to which the disclosure pertains by referencing the claims, with functional equivalents thereof to be included therein.

What is claimed is:

1. A display device comprising:
a substrate including a display area and a pad area; and
a data conductive layer disposed on the substrate in the pad area;
wherein the data conductive layer comprises a data base layer, a data main metal layer disposed on the data base layer, a first data capping layer disposed on the data main metal layer, a second data capping layer disposed on the first data capping layer, and a plurality of metal aggregates disposed on the second data capping layer.

2. The display device of claim 1, wherein the plurality of metal aggregates are formed of an inactive metal.

3. The display device of claim 2, wherein the inactive metal comprises at least one metal selected from silver (Ag), gold (Au), and platinum (Pt).

4. The display device of claim 1, wherein the second data capping layer is formed of a transparent conductive oxide.

5. The display device of claim 4, wherein the second data capping layer comprises indium tin zinc oxide (IGZO).

6. The display device of claim 5, wherein the second data capping layer has a thickness of about 100 Å to about 500 Å.

7. The display device of claim 4, wherein the first data capping layer comprises titanium nitride (TiN).

8. The display device of claim 7, wherein the first data capping layer has a thickness of about 100 Å to about 500 Å.

9. The display device of claim 7, wherein the data main metal layer comprises aluminum (Al).

10. The display device of claim 7, wherein the data base layer comprises titanium (Ti).

11. The display device of claim 1, wherein the data main metal layer is thicker than the data base layer, the first data capping layer, and the second data capping layer.

12. The display device of claim 10, wherein the data main metal layer has a thickness of 5,000 Å to 20,000 Å.

13. The display device of claim 11, wherein the data base layer has a thickness of 300 Å to 700 Å.

14. The display device of claim 1, wherein the substrate is any one of a rigid substrate, a flexible substrate, and an ultra thin glass (UTG) substrate.

15. A method for manufacturing a display device comprising:
sequentially forming a patterned data base layer, a data main metal layer, a first data capping layer, and a second data capping layer on a substrate;
forming a metal material layer on the second data capping layer; and
forming a metal aggregate by applying heat to the metal material layer such that metal comprised in the metal material layer is agglomerated.

16. The method of claim 15, wherein the metal material layer comprises an inactive metal.

17. The method of claim 16, wherein the inactive metal comprises at least one metal selected from silver (Ag), gold (Au), and platinum (Pt).

18. The method of claim 16, wherein in the forming of the metal aggregate by applying the heat to the metal material layer such that metal comprised in the metal material layer is agglomerated,
the heat is in a range of 100° C. to 250° C.

19. The method of claim 16, wherein the metal aggregate comprises at least one metal selected from silver (Ag), gold (Au), and platinum (Pt).

20. The method of claim 16, wherein the second data capping layer comprises indium tin zinc oxide (IGZO), the first data capping layer comprises titanium nitride (TiN), the data main metal layer comprises aluminum (Al), and the patterned data base layer comprises titanium (Ti).
